(19) United States
(12) Patent Application Publication
(10) Pub. No.: US 2013/0048828 A1
(43) Pub. Date: Feb. 28, 2013

(54) ADJUSTABLE SUPPORTING ASSEMBLY

(71) Applicant: CHIEN-HUNG LEE, New Taipei (TW)

(72) Inventor: CHIEN-HUNG LEE, New Taipei (TW)

(73) Assignee: HON HAI PRECISION INDUSTRY CO., LTD., New Taipei (TW)

(21) Appl. No.: 13/244,667

(22) Filed: Sep. 25, 2011

(30) Foreign Application Priority Data
Aug. 25, 2011 (TW) 100215862

(51) Int. Cl. H05K 7/00; F16M 13/00

(52) U.S. Cl. 248/688; 248/354.5

(57) ABSTRACT

A supporting assembly is mounted on an electronic product to adjust visual angles of the electronic product, and includes a fixed member, a movable member, a pair of flexible members and an adjusting member. The extending segment defines a plurality of recess portions spaced from each other. The adjusting member includes a pair of latching ends on two ends of the adjusting member to be opposite to the recess portions. A distance between the movable member and the fixed member can be adjusted by controlling the adjusting member to urge the pair of latching ends selectively engaging with the recess portions, so as to adjust visual angles of the electronic product.

### BACKGROUND

1. Technical Field

The present disclosure relates to a supporting assembly, and more particularly to a length-adjustable supporting assembly.

2. Description of Related Art

Electronic products, such as digital photo frames, pad computers, notebook computers, Personal Digital Assistants (PDA), mobile telephones and Voice over Internet Protocol Phones (VoIP Phone), and so on, are indispensable equipments for people's daily life. Generally, a supporting assembly is accompanied or attached to the electronic product in a fixed visual angle for providing viewing convenience. However, the fixed visual angle could not meet different requirements of various using situations or users.

Therefore, a need exists in the industry to overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a perspective view of one exemplary embodiment of a supporting assembly in accordance with the present disclosure.

FIG. 2 is a disassembled view of the exemplary embodiment of the supporting assembly of FIG. 1 in a direction.

FIG. 3 is a disassembled view of the exemplary embodiment of the supporting assembly of FIG. 1 in another direction.

FIG. 4 is a perspective view of the exemplary embodiment of an adjusting member of the supporting assembly in accordance with the present disclosure.

FIG. 5 is a perspective view of the exemplary embodiment of the supporting assembly in a first position in accordance with the present disclosure.

FIG. 6 is a perspective view of the exemplary embodiment of the supporting assembly in a second position in accordance with the present disclosure.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

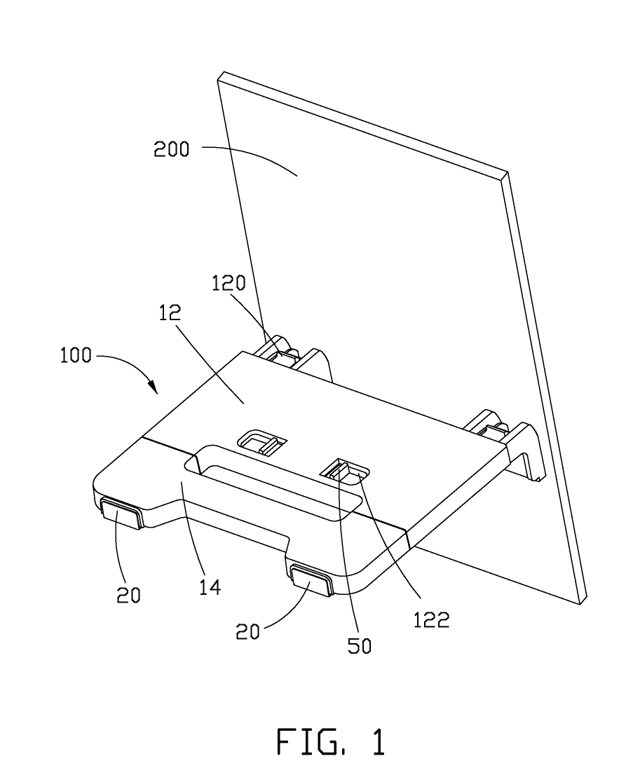

Referring to FIG. 1, a supporting assembly 100 is mounted on an electronic product 200 to adjust visual angles of the electronic product 200. The electronic product 200 may be a digital photo frame, a pad computer, or a Voice over Internet Protocol Phone (VoIP Phone).

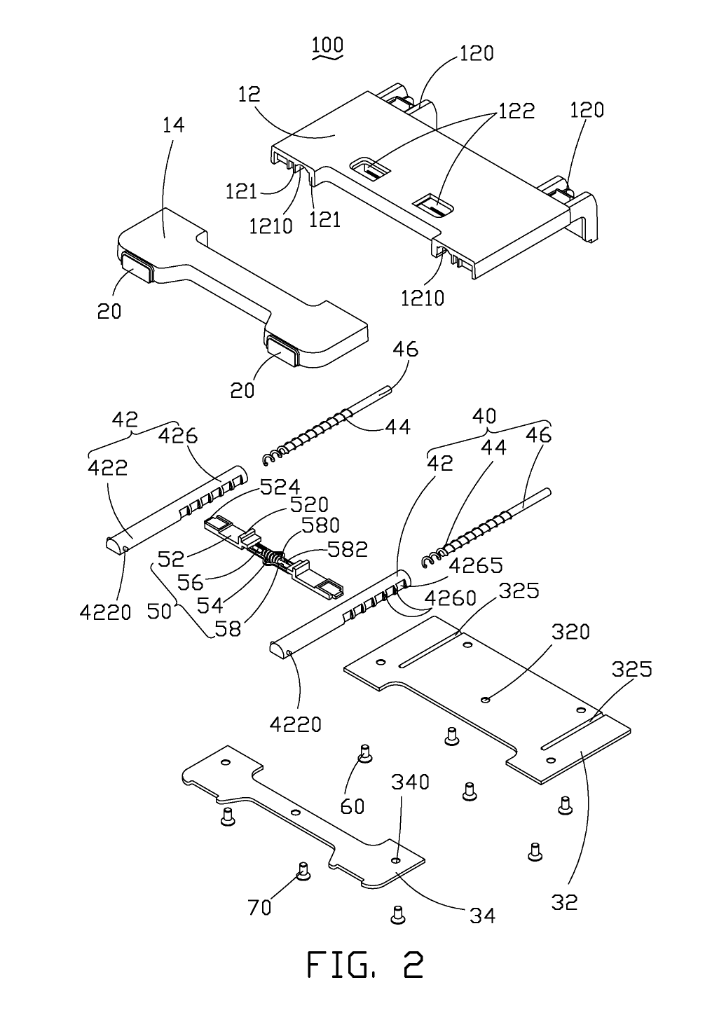

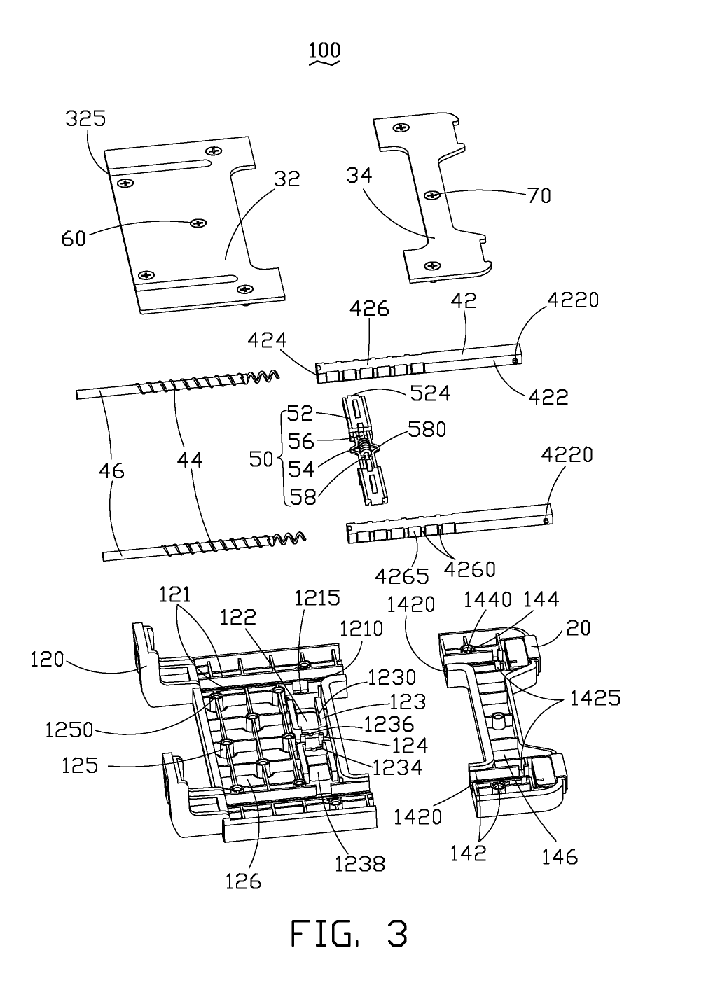

Referring to FIG. 2 and FIG. 3, the supporting assembly 100 comprises a fixed member 12, a movable member 14, a pair of foot pads 20, a pair of flexible members 40 and an adjusting member 50. The fixed member 12 is securely mounted on the electronic product 200, the movable member 14 is movably mounted on an end of the fixed member 12 away from the electronic product 200, and the pair of foot pads 20 are attached on the movable member 14 to support the electronic product 200.

Each of the pair of flexible members 40 comprises a fixing segment 422 and an extending segment 426 extending from the fixing segment 422. The fixing segment 422 is installed in one of the fixed member 12 and the movable member 14 and the extending segment 426 extends to the other one of the fixed member 12 and the movable member 14 to engage with the adjusting member 50 installed between the extending segments 426. A distance between the movable member 14 and the fixed member 12 can be adjusted by controlling the adjusting member 50. Therefore, a length of the supporting assembly 100 can be adjusted to provide suitable visual angles of the electronic product 200.

The fixed member 12 comprises a pair of connecting portions 120 and two pairs of first positioning portions 121. The pair of connecting portions 120 are configured on one end of the fixed member 12 away from the movable member 14 and is connected with the electronic product 200 to fix the supporting assembly 100 on the electronic product 200. Each pair of first positioning portions 121 perpendicularly protrude outwardly from a first surface 126 of the fixed member 12, and are parallel with and spaced from each other to collectively form a first receiving groove 1210 with the first surface 126. The first receiving groove 1210 extends from the corresponding connecting portion 120 towards the movable member 14 and has a first open side for movably accommodating the flexible member 40 in the first receiving groove 1210.

In the illustrated embodiment, the fixed member 12 further comprises two pairs of blocking walls 123 perpendicular to the first positioning portions 121 and collectively defining a pair of adjusting holes 122. Each pair of the blocking walls 123 perpendicularly protrude outwardly from the first surface 126, and are parallel with and spaced from each other to collectively form a receiving cavity 1238 for partially accommodating the adjusting member 50. Each of the pair of adjusting holes 122 is defined between the pair of blocking walls 123 and passes through the first surface 126 to partially receive the adjusting member 50.

In the illustrated embodiment, each of the pair of the adjusting holes 122 communicates with the corresponding receiving cavity 1238, and the adjusting member 50 is received in the receiving cavity 1238 and partially passes through the pair of adjusting holes 122 to be exposed out of the fixed member 12 for convenient operation.

In the illustrated embodiment, one of the pair of first positioning portions 121 defines a first opening 1215 configured between the pair of blocking walls 123 and on a side of the receiving cavity 1238, and the fixed member 12 defines a pair of second openings 1234. Each of the pair of second openings 1234 is opposite to the corresponding first opening 1215, and configured between the pair of blocking walls 123 and on the other side of the receiving cavity 1238. That is, the first opening 1215 and the corresponding second opening 1234 are respectively formed on two ends of the pair of blocking walls 123 and communicate with the receiving cavity 1238.

In the illustrated embodiment, the adjusting member 50 is movably received in the receiving cavity 1238 to move between the first opening 1215 and the second opening 1234, and partially extends through the first opening 1215 into the first receiving groove 1210 to engage with the flexible member 40.

The movable member 14 comprises two pairs of second positioning portions 142 corresponding to the two pairs of first positioning portions 121. Each pair of second positioning portions 142 are parallel with and spaced from each other, and perpendicularly protrude outwardly from a second surface 146 of the movable member 14 to collectively form a second receiving groove 1420 with the second surface 126. The second receiving groove 1420 extends from one end of the movable member 14 where the foot pad 20 is fixed towards the fixed member 12 and has a second open side opposite to the first open side for the flexible member 40 passing through. The first receiving groove 1210 and the second receiving groove 1420 are oppositely collinear with each other and respectively receive part of the corresponding flexible member 40. In the illustrated embodiment, the first receiving groove 1210 communicates with the second receiving groove 1420 to collectively receive the flexible member 40 when the movable member 14 closes with the fixed member 12.

In the illustrated embodiment, centers of each of the pair of connecting portions 120, the first receiving groove 1210, the second receiving groove 1420 and the corresponding foot pads 20 are on a same line.

The supporting assembly 100 further comprises a first bottom cover 32 engaging with the fixed member 12 and a second bottom cover 34 engaging with the movable member 14. The first bottom cover 32 defines a plurality of first through holes 320 and the second bottom cover 34 defines a plurality of second through holes 340. The fixed member 12 comprises a plurality of first fixing poles 125 and the movable member 14 comprises a plurality of second fixing poles 144. Each of the plurality of first fixing poles 125 protrudes outwardly from the first surface 126 and defines a first fixing hole 1250 opposite to the corresponding first through hole 320, and each of the plurality of second fixing poles 144 protrudes outwardly from the second surface 146 and defines a second fixing hole 1440 opposite to the corresponding second through hole 340. A first screw 60 passes through the first through hole 320 and is screwed into the corresponding first fixing hole 1250 to securely fix the first bottom cover 32 on the fixed member 12. Similarly, a second screw 70 passes through the second through hole 340 and is screwed into the corresponding second fixing hole 1440 to securely fix the second bottom cover 34 on the movable member 14.

Each of the pair of flexible members 40 comprises a guide sleeve 42 defining a sleeve hole 424, a first spring 44 and a movable shaft 46. The first spring 44 is coiled around the movable shaft 46 to be collectively received in the sleeve hole 424 to make an elastic connection between the movable member 14 and the fixed member 12. The fixing segment 422 and the extending segment 426 are configured on the guide sleeve 42, and the sleeve hole 424 is defined through an end of the extending segment 426 towards the fixing segment 422 along the guide sleeve 42.

In the illustrated embodiment, the fixing segment 422 is partially received in the second receiving groove 1420 of the movable member 14, the extending segment 426 is partially received in the first receiving groove 1210 of the fixed member 12, and the first spring 44 resists between bottom of the sleeve hole 424 and the fixed member 12 to elastically connect the movable member 14 with the fixed member 12.

In the illustrated embodiment, each pair of second positioning portions 142 define a pair of latching holes 1425 configured on a side of the second positioning portion 142 contiguous with the corresponding foot pad 20 and communicating with the second receiving groove 1420 to engage with the fixing segment 422 of the guide sleeve 42, and the guide sleeve 42 comprises a pair of latching protrusions 4220 protruding from two sides of the fixing segment 422away from the extending segment 426. The pair of latching protrusions 4220 are latched in the latching holes 1425 to securely fix the guide sleeve 42 in the movable member 14 with the guide sleeve 42 receiving in the second receiving groove 1420. The guide sleeve 42 moves towards the fixed member 12 along the second receiving groove 1420 and the first receiving groove 1210, and the first spring 44 is compressed by pushing the movable member 14 moving towards the fixed member 12.

The guide sleeve 42 comprises a plurality of blocking portions 4260 protruding outwardly from sides of the extending segment 426. Each two adjacent blocking portions 4260 collectively form a recess portion 4265 to engage with the adjusting member 50.

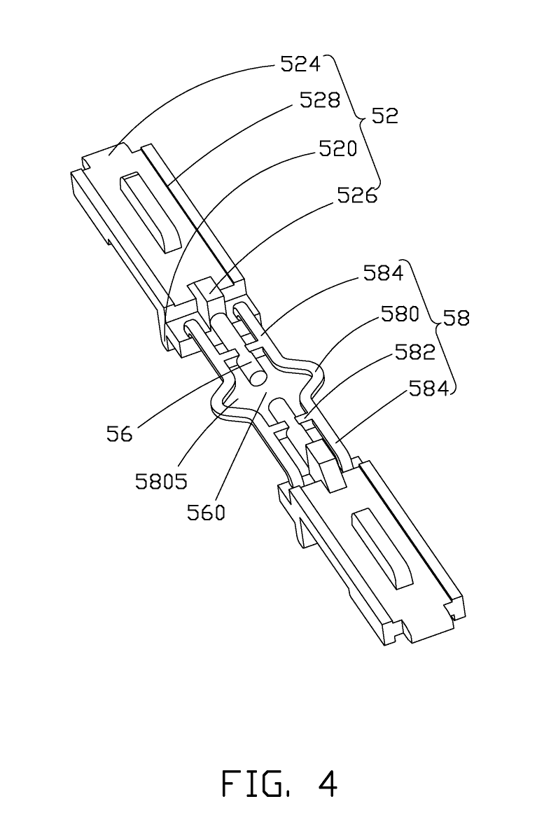

Referring to FIG. 4, in the illustrated embodiment, the adjusting member 50 is movably mounted in the fixed member 12 to engage with the flexible member 40. The adjusting member 50 comprises a pair of latching portions 52, a second spring 54, a pair of fixing shafts 56 and a pair of elastic arms 58.

Each of the pair of latching portions 52 is received in the receiving cavity 1238 to engage with the guide sleeve 42, and comprises a knob 520, a latching end 524, a fixing end 526 and a pair of latching sides 528. The knob 520 protrudes outwardly from the corresponding latching portion 52 towards the adjusting hole 122 and is contiguous with the fixing end 526. Each of the pair of latching portions 52 is received in the receiving cavity 1238 to accommodate the knob 520 in the adjusting hole 122 for operation.

The latching end 524 and the fixing end 526 are respectively configured on two opposite ends of the latching portion 52. The latching end 524 and passes through the first opening 1215 to engage with one of the recess portions 4265 of the guide sleeve 42 to limit the guide sleeve 42 moving relative to the fixed member 12. The fixing end 526 faces to the second opening 1234 and is uses to securely connect with the pair of fixing shafts 56 and the pair of the elastic arms 58. In other words, each of the pair of latching portions 52 is accommodated in the receiving cavities 1238 with the latching end 524 passing through the first opening 1215 to engage with the recess portions 4265 and the fixing end 526 facing to the second opening 1234.

The pair of latching sides 528 are configured between the latching end 524 and the fixing end 526 and located on a side of the latching portion 52 away from the knob 520. Each blocking walls 123 of the fixed member 12 comprises a projecting portion 1230 protruding outwardly from the corresponding blocking wall 123 towards the receiving cavity 1238. Each of the pair of latching portions 52 is resisted between the

Page 10 of 24 pair of blocking walls 123 to be movably received in the receiving cavity 1238, the knob 520 passes through the adjusting hole 122 to be exposed out from the fixed member 12, and the pair of latching sides 528 are resisted on the projecting portions 1230 to restrict the latching portion 52 within the receiving cavity 1238.

To engage the latching end 524 with the recess portion 4265, each of the pair of latching portions 52 moves from the second opening 1234 towards the first opening 1215 in the receiving cavity 1238 by pushing the pair of knobs 520 moving away from each other. Similarly, to disengage the latching end 524 from the recess portion 4265, each of the pair of latching portions 52 moves from the first opening 1215 towards the second opening 1234 in the receiving cavity 1238 by pushing the pair of knobs 520 moving together with each other.

Each of the pair of elastic arms 58 comprises a pair of arm portions 584 and a bending portion 580 between the pair of arm portions 584. Each of the pair of arm portions 584 is fixed on the fixing end 526 to connect the corresponding elastic arm 58 between the pair of latching portions 52. In the illustrated embodiment, the pair of arm portions 584 are integrally formed with the bending portion 580. The pair of arm portions 584 and the bending portion 580 collectively form a receiving portion 5805, and the fixed member 12 further comprises a pair of protruding posts 124 protruding outwardly from the first surface 126 and configured between the two pairs of blocking walls 123 to engage with the receiving portion 5805. In assembling, the bending portion 580 circles around the corresponding protruding post 124 and is received in the receiving portion 5805 to elastically mount the adjusting member 50 on the fixed member 12.

Each of the pair of elastic arms 58 further comprises a pair of resisting portions 582. Each of the pair of resisting portions 582 protrudes from the corresponding arm portion 584 towards the fixing shaft 56 and is configured between the fixing end 526 and the bending portion 580. One end of the fixing shaft 56 is fixed on the fixing end 526 and configured between the two opposite arm portions 584, and the other end is free to extend along the arm portion 584 towards the bending portion 580.

The adjusting member 50 defines a gap portion 560 formed between the fixing shafts 56. The second spring 54 passes through the gap portion 560 to coil around the fixing shafts 56, and resist between the resisting portions 582, so as to elastically connect between the pair of latching portions 52.

In assembly, the first spring 44 coiling around the movable shaft 46 is received in the sleeve hole 424 of the guide sleeve 42 so as to assemble the flexible member 40. The pair of latching protrusions 4220 are latched in the latching holes 1425 to securely receive the fixing segment 422 in the second receiving groove 1420 and movably receive the extending segment 426 in the first receiving groove 1210. Therefore, the flexible member 40 elastically connects between the fixed member 12 and the movable member 14. The pair of latching portions 52 are received in the corresponding receiving cavities 1238with the latching sides 528 resisting on the projecting portions 1230, with the knob 520 passing through the receiving cavity 1238 to be exposed out of the adjusting hole 122, and with the latching end 524 facing to the first opening 1215 and the fixing end 526 facing to the second opening 1234, and the bending portions 580 circle around the pair of protruding posts 124 and the second spring 54 coils around the fixing shafts 56 to resist on the resisting portions 582. Therefore, the adjusting member is elastically mounted in the fixed member 12. The first bottom cover 32 covers on the fixed member 12 and the second bottom cover 34 covers on the movable member 14. The first screw 60 passes through the first through hole 320 and is screwed into the corresponding first fixing hole 1250 to securely fix the first bottom cover 32 on the fixed member 12. Similarly, the second screw 70 passes through the second through hole 340 and is screwed into the corresponding second fixing hole 1440 to securely fix the second bottom cover 34 on the movable member 14. Therefore, the supporting assembly 100 is assembled.

The latching end 524 passes through the first opening 1215 to urge in the recess portion 4265 by pushing the pair of knobs 520 moving away from each other, so that the movable member 14 is securely connected with the fixed member 12 via engaging the adjusting member 50 with the flexible member 40. The latching end 524 disengages from the recess portion 4265 by pushing the pair of knobs 520 moving together, so that a distance of the flexible member 40 can be adjusted to adjust a distance between the fixed member 12 and the movable member 14.

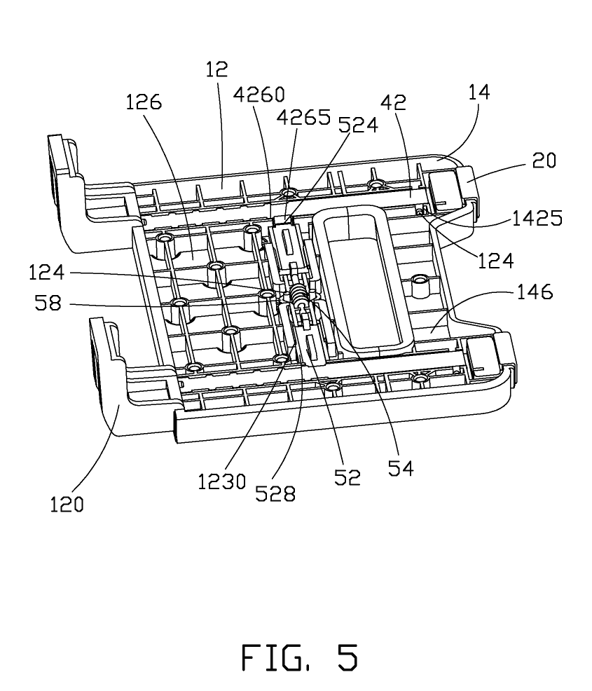

Referring to FIG. 5, by pushing the pair of knobs 520 moving together, each of the pair of latching portions 52 moves from the first opening 1215 towards the second opening 1234 in the receiving cavity 1238, the second spring 54 is compressed and the pair of elastic arms 58 are in compressing deformation to disengage the pair of latching ends 524 from the corresponding recess portions 4265, in this condition, under an external force, the movable member 14 is urged to move towards the fixed member 12 and the first spring 44 and the movable shaft 46 completely receiving in the sleeve hole 424 of the guide sleeve 42, so that, a distance between the movable member 14 and the fixed member 12 is shortened. At this time, by releasing the pair of knobs 520, the second spring 54 is freely extended to urge the pair of latching ends 524 moving towards the pair of first openings 1215 to engage with the pair of recessing portions 4265 which are on ends of the pair of extending segments 426 away from the fixing segments 422, so as to abut the movable member 14 against the fixed member 12. Therefore, the distance between the movable member 14 and the fixed member 12 is shortest, that is, the supporting member 100 is in a first position with a shortest length.

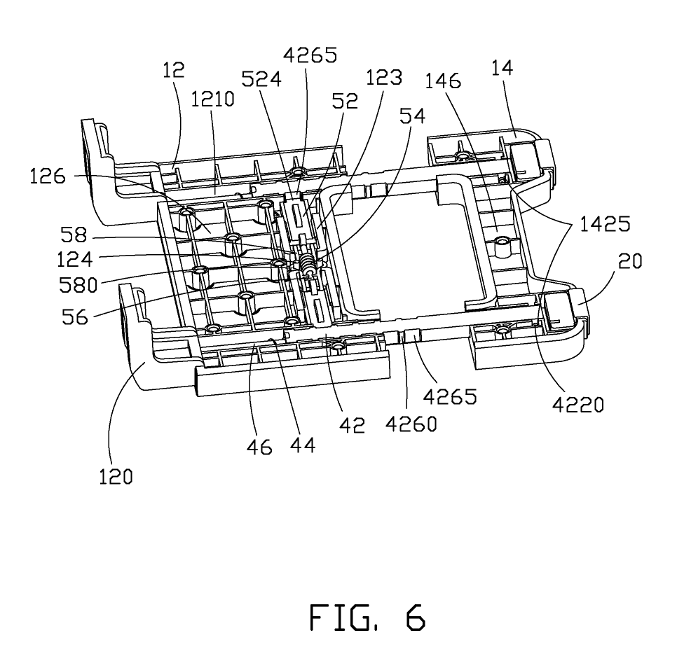

Referring to FIG. 6, by pushing the pair of knobs 520 moving together, each of the pair of latching portions 52 moves from the first opening 1215 towards the second opening 1234 in the receiving cavity 1238, the second spring 54 is compressed and the pair of elastic arms 58 are in compressing deformation to disengage the pair of latching ends 524 from the corresponding recess portions 4265, in this condition, under an external force, the movable member 14 is urged to move away from the fixed member 12 and the first spring 44 urges the movable shaft 46 moving from the sleeve hole 424 of the guide sleeve 42 to elongate the flexible member 40, so that, the distance between the movable member 14 and the fixed member 12 is elongated. At this time, by releasing the pair of knobs 520, the second spring 54 is freely extended to urge the pair of latching ends 524 moving towards the pair of first openings 1215 to engage with the pair of recessing portions 4265 which is on ends of the extending segments 426 nearing the fixing segments 422, so as to separate the movable member 14 away from the fixed member 12. Therefore, the distance between the movable member 14 and the fixed member 12 is farthest, that is, the supporting member 100 is in a second position with a longest length.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. A supporting assembly mounted on an electronic product to adjust visual angles of the electronic product, and comprising a fixed member, a movable member, a pair of flexible members and an adjusting member, each of the pair of flexible members comprising a fixing segment and an extending segment extending from the fixing segment, the extending segment defining a plurality of recess portions spaced from each other, the adjusting member comprising a pair of latching ends on two ends of the adjusting member to be opposite to the recess portions, the fixing segment installed in one of the fixed member and the movable member and the extending segment extending to the other one of the fixed member and the movable member to engage with the adjusting member installed between the extending segments, wherein a distance between the movable member and the fixed member can be adjusted by controlling the adjusting member to urge the pair of latching ends selectively engaging with the recess portions, so as to adjust visual angles of the electronic product.

2. The supporting assembly as claimed in claim 1, wherein the fixed member comprises two pairs of first positioning portions, each pair of which are parallel with and space from each other to collectively form a first receiving groove to accommodate part of the corresponding flexible member.

3. The supporting assembly as claimed in claim 2, wherein the movable member comprises two pairs of second positioning portions, each pair of which are parallel with and spaced from each other to collectively form a second receiving groove to accommodate another part of the corresponding flexible member.

4. The supporting assembly as claimed in claim 3, wherein the first receiving grooves respectively communicate and are collinear with the second receiving grooves to collectively receive the corresponding flexible members.

5. The supporting assembly as claimed in claim 4, wherein each of the flexible members comprises a guide sleeve defining a sleeve hole, a first spring and a movable shaft, the fixing segment and the extending segment are configured on the guide sleeve, and the sleeve hole is defined through an end of the extending segment towards the fixing segment along the guide sleeve, the first spring is coiled around the movable shaft to be collectively received in the sleeve hole to make an elastic connection between the movable member and the fixed member.

6. The supporting assembly as claimed in claim 5, wherein each pair of second positioning portions define a pair of latching holes, the guide sleeve comprises a pair of latching protrusions protruding from two sides of the fixing segment, the pair of latching protrusions are latched in the latching holes to fix the guide sleeve in the movable member.

7. The supporting assembly as claimed in claim 2, wherein a pair of first openings opposite to each other are defined in the first positioning portion contiguous with the adjusting member, the pair of latching ends pass through the pair of first opening to engage with the recess portions so as to fix the flexible member in the adjusting member.

8. The supporting assembly as claimed in claim 7, wherein the fixed member further comprises two pairs of blocking walls perpendicularly configured between the first positioning portions, each pair of blocking walls are parallel with and spaced from each other to collectively form a receiving cavity for accommodating the adjusting member.

9. The supporting assembly as claimed in claim 8, wherein the fixed member defines a pair of adjusting holes, each of which is configured between the pair of blocking walls and communicates with the receiving groove, the adjusting member is received in the receiving cavity and comprises a pair of knobs passing through the pair of adjusting holes to be exposed out of the fixed member for operation.

10. The supporting assembly as claimed in claim 9, wherein the adjusting member comprises a pair of latching portions received in the receiving cavities to engage with the guide sleeve, each of the pair of latching portions comprises a pair of latching sides away from the knob, each of the plurality of blocking walls comprises a projecting portion protruding outwardly from the corresponding blocking wall towards the receiving cavity, each of the pair of latching portions is resisted between the pair of blocking walls to be movably received in the receiving cavity and the pair of latching sides resists on the projecting portions to restrict the latching portion within the receiving cavity.

11. The supporting assembly as claimed in claim 10, wherein the fixed member defines a pair of second openings opposite to the pair of first openings and configured between the pair of adjusting holes, each of the pair of latching portions moving from the second opening towards the first opening in the receiving cavity by controlling the pair of knobs.

12. The supporting assembly as claimed in claim 11, wherein each of the pair of latching portions comprises a fixing end opposite to the latching end, the adjusting member comprises a pair of fixing shafts and a pair of elastic arms fixed on the fixing ends to connecting with the pair of latching portions.

13. The supporting assembly as claimed in claim 12, wherein each of the pair of elastic arms comprises a pair of arm portions and a bending portion between the pair of arm portions, each of the pair of arm portions is fixed on the fixing end and each of the pair of fixing shafts is configured between the pair of elastic arms and parallel with the arm portions.

14. The supporting assembly as claimed in claim 13, wherein the pair of arm portions are integrally formed with the bending portion, and collectively forms a receiving portion with the bending portion to engage with the fixed member.

15. The supporting assembly as claimed in claim 14, wherein the fixed member comprises a pair of protruding posts configured between the two pairs of blocking walls, the bending portion circles around the corresponding protruding post and is received in the receiving portion so as to elastically mount the adjusting member on the fixed member.

16. The supporting assembly as claimed in claim 13, wherein the adjusting member defines a gap portion formed between the fixing shafts, the adjusting member comprises a second spring passing through the gap portion to coil around the fixing shafts and to elastically connect between the pair of latching portions.

17. The supporting assembly as claimed in claim 16, wherein each of the pair of elastic arms further comprises a pair of resisting portions protruding from the corresponding arm portions towards the fixing shafts and is configured between the fixing end and the bending portion, the second spring resists on the resisting portions.

18. A supporting assembly used to adjust visual angels of an electronic product, comprising a pair of flexible members and an adjusting member movably attached to the electronic product, each of the flexible members comprising a fixing segment fixed on the electronic product and an extending segment extending from the fixing segment to be a free end, the extending segment defining a plurality of recess portions spaced from each other, the adjusting member comprising a pair of latching ends opposite to the recess portions, wherein the pair of latching ends selectively engage with the recess portions to movably position the adjusting member on the flexible member.

19. The supporting assembly as claimed in claim 18, further comprising a fixed member, in which the fixing segment is installed, and a movable member, in which the extending segment and the adjusting member are received, a distance between the movable member and the fixed member can be adjusted by adjusting the latching ends of the adjusting member to engage different one of the plurality of recess portions.

20. A supporting assembly mounted on an electronic product to adjust visual angles of the electronic product, the supporting assembly comprising a fixed member, a movable member slideable relatively to the fixed member along at least one flexible member connecting the movable member to the fixed member, and an adjusting member to lock the movable member at different positions relative to the fixed member, wherein the at least one flexible member drives the movable member move relative to the fixed member upon removing the lock of the adjusting member.
